(19) United States
(12) Patent Application Publication
(10) Pub. No.: US 2025/0178870 A1
(43) Pub. Date: Jun. 5, 2025

(54) TRANSFERRING APPARATUS

(71) Applicant: SEMES CO., LTD., Chungcheongnam-do (KR)

(72) Inventors: Ju Ho LEE, Gyeonggi-do (KR); Seok Hee KIM, Gyeonggi-do (KR); Eun Sang YOON, Gyeonggi-do (KR)

(21) Appl. No.: 18/950,077

(22) Filed: Nov. 16, 2024

(30) Foreign Application Priority Data
Dec. 5, 2023 (KR) 10-2023-0174323

(51) Int. Cl. B66C 11/16; B66C 13/06; B66C 19/00

(52) U.S. Cl. CPC B66C 11/16; B66C 13/06; B66C 19/00

(57) ABSTRACT

A transferring apparatus comprises a driving unit provided with a driving wheel and connected with a housing; a hoist unit provided in the housing; and a hand unit provided with a gripper that grips a transfer target, wherein the hoist unit includes: a belt unit connected to the hand unit, including a first hoist belt and a second hoist belt; and a hoist driving unit configured to wind or unwind the belt unit, and each of a first surface of the first hoist belt and a second surface of the second hoist belt is disposed to be misaligned at an angle with a driving direction of the driving unit without being parallel with the driving direction of the driving unit.

### CROSS-REFERENCE TO RELATED APPLICATION

This application claims priority from Korean Patent Application No. 10-2023-0174323 filed on Dec. 5, 2023 in the Korean Intellectual Property Office and all the benefits accruing therefrom under 35 U.S.C. 119, the contents of which in its entirety are herein incorporated by reference.

### BACKGROUND

### Technical Field

The present disclosure relates to a transferring apparatus.

### Description of the Related Art

A semiconductor device fabricating process may be continuously performed in a semiconductor fabricating facility, and may be divided into a pre-process and a post-process. The semiconductor fabricating facility may be installed in a space defined as a fab (FAB) to fabricate a semiconductor device.

The pre-process refers to a process of completing a chip by forming a circuit pattern on a substrate (e.g., a wafer). This pre-process may include a deposition process of forming a thin film on a substrate, a photo lithography process of transferring a photoresist on the thin film by using a photo mask, an etching process of selectively removing an unnecessary portion by using chemicals or reactive gases to form a desired circuit pattern on the substrate, an ashing process of removing the photoresist remaining after etching, an ion implantation process of injecting ions into a portion connected to the circuit pattern to have characteristics of an electronic device, and a cleaning process of removing pollutants on the substrate.

The post-process refers to a process of evaluating performance of the product completed through the pre-process. The post-process may include a substrate inspection process of selecting good products and defects by inspecting the operation of each chip on the substrate, a package process of cutting and separating each chip through dicing, die bonding, wire bonding, molding, marking, etc. to make a shape of the product, and a final inspection process of finally inspecting characteristics and reliability of the product through electrical characteristics inspection, burn-in inspection, etc.

An article such as a substrate may be transferred by a transferring apparatus while being accommodated in a container. The transferring apparatus may move between substrate processing apparatuses, or may move to another fab or another factory to transport the article.

Meanwhile, the transferring apparatus may be provided with a plurality of hoist belts in order to move up and down to a position where the container is placed. The hoist belt is disposed so that its width is parallel with a driving direction of the transferring apparatus, whereby a large deformation rate of the hoist belt may occur in a direction (a direction in which a hand unit slides) perpendicular to the driving direction of the transferring apparatus.

Therefore, the transferring apparatus is vulnerable to a shaking response of the hand unit, and thus the position of the hand unit may be set in error. As a result, a gripper of the hand unit may be incorrectly fitted into the container, or an error may occur in an oscillation/optical sensor that detects the hand unit, due to shaking of the hoist belt, whereby improvement is required.

### BRIEF SUMMARY

An object of the present disclosure is to provide a transferring apparatus that may minimize shaking of a belt unit moving a hand unit in a vertical direction.

The objects of the present disclosure are not limited to those mentioned above and additional objects of the present disclosure, which are not mentioned herein, will be clearly understood by those skilled in the art from the following description of the present disclosure.

A transferring apparatus according to one aspect of the present disclosure devised to achieve the above objects comprises a driving unit provided with a driving wheel and connected with a housing; a hoist unit provided in the housing; and a hand unit provided with a gripper that grips a transfer target, wherein the hoist unit includes: a belt unit connected to the hand unit, including a first hoist belt and a second hoist belt; and a hoist driving unit configured to wind or unwind the belt unit, and each of a first surface of the first hoist belt and a second surface of the second hoist belt is disposed to be misaligned at an angle with a driving direction of the driving unit without being parallel with the driving direction of the driving unit.

A transferring apparatus according to another aspect of the present disclosure devised to achieve the above objects comprises a driving unit provided with a driving wheel and connected with a housing; a hoist unit provided in the housing; a horizontal moving unit moving in a direction orthogonal to a driving direction of the driving unit between the housing and the hoist unit to move the hoist unit relative to the housing; and a hand unit provided with a gripper that grips a transfer target, wherein the hoist unit includes: a belt unit connected to the hand unit, including a first hoist belt and a second hoist belt; and a hoist driving unit configured to wind or unwind the belt unit, and a first surface of the first hoist belt and a second surface of the second hoist belt are disposed in an X shape by crossing each other at an upper portion, and are extended in a downward direction.

A transferring apparatus provided in a semiconductor fabricating factory according to other aspect of the present disclosure devised to achieve the above objects comprises a driving unit provided with a driving wheel and connected with a housing; a hoist unit provided in the housing; a horizontal moving unit moving in a direction orthogonal to a driving direction of the driving unit between the housing and the hoist unit to move the hoist unit relative to the housing; and a hand unit provided with a gripper that grips a transfer target, wherein the hoist unit includes: a belt unit connected to the hand unit, including a first hoist belt, a second hoist belt and a third hoist belt; and a hoist driving unit configured to wind or unwind the belt unit, the hoist driving unit includes: a motor provided with a motor shaft; a driving pulley connected to the motor shaft to receive a rotational force of the motor; a driven pulley connected to the driving pulley by a timing belt; an input shaft extended to both sides of the driven pulley; a first bevel gear connected to one end of the input shaft at an acute angle; a second bevel gear connected to the other end of the input shaft at an obtuse angle symmetrical with the first bevel gear; a first output shaft connected to the first bevel gear; a second output shaft connected to the second bevel gear; a first drum connected to the first output shaft, on which the first hoist belt is wound; a second drum connected to the second output shaft, on which the second hoist belt is wound; a third drum surrounding the input shaft to receive a rotational force of the input shaft, on which the third hoist belt is wound, and disposed between the first drum and the second drum; a first guide roller guiding movement of the first hoist belt while facing the first drum; a second guide roller guiding movement of the second hoist belt while facing the second drum; a third guide roller guiding movement of the third hoist belt while facing the third drum; a first anti-shaking plate on which the first hoist belt is disposed between the first guide rollers; a second anti-shaking plate on which the second hoist belt is disposed between the second guide rollers; and a third anti-shaking plate on which the third hoist belt is disposed between the third guide rollers, each of a first surface of the first hoist belt and a second surface of the second hoist belt is disposed toward a central direction of the housing rather than the driving direction of the driving unit, and thus is disposed to be misaligned at an angle without being parallel with each of the driving direction of the driving unit and the moving direction of the horizontal moving unit, the first surface between the first drum and the first guide roller and the second surface between the second drum and the second guide roller cross each other to constitute an ‘X’ shape, and a third surface of the third hoist belt faces a point where the first surface of the first hoist belt and the second surface of the second hoist belt cross each other.

Details of the other embodiments are included in the detailed description and drawings.

In the transferring apparatus according to the present disclosure, three hoist belts are disposed to face a central direction between a hoist unit and a hand unit, so that a deformation rate at which the three hoist belts are deformed in a direction of sliding a horizontal moving unit may be reduced, that is, shaking of the belt unit may be reduced. Therefore, since shaking in which the operation of the hand unit interworks with the belt unit may be reduced, stability in a gripping operation of the hand unit may be improved, and various error causes such as gripper gripping error and an oscillation error due to shaking of the hand unit may be improved, whereby facility quality may be improved.

The effects according to the embodiment of the present disclosure are not limited to those mentioned above, and more various effects are included in the following description of the present disclosure.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a view illustrating a fabricating factory in which a transferring apparatus according to some embodiments of the present disclosure is provided;

FIG. 2 is a view illustrating a state that a transferring apparatus according to some embodiments of the present disclosure descends toward a transfer target;

FIG. 3 is a view illustrating an area A of FIG. 2;

FIG. 4 is a view illustrating a state that a transferring apparatus according to some embodiments of the present disclosure grips a transfer target;

FIG. 5 is a view illustrating a state that a belt unit of a transferring apparatus according to some embodiments of the present disclosure is unwound;

FIG. 6 is a view illustrating a belt unit of a transferring apparatus according to some embodiments of the present disclosure;

FIG. 7 is a perspective view illustrating a hoist unit of a transferring apparatus according to the first embodiment of the present disclosure;

FIG. 8 is a rear view illustrating a hoist unit of a transferring apparatus according to the first embodiment of the present disclosure;

FIG. 9 is a plan view illustrating a hoist unit of a transferring apparatus according to the first embodiment of the present disclosure;

FIG. 10 is a plan view illustrating a hoist unit of a transferring apparatus according to the second embodiment of the present disclosure;

FIG. 11 is a plan view illustrating a hoist unit of a transferring apparatus according to the third embodiment of the present disclosure;

FIG. 12 is a view illustrating arrangement of a hoist belt according to a comparative example;

FIG. 13 is a view illustrating a transfer track in a driving direction of a hand unit of a transferring apparatus according to a comparative example; and

FIG. 14 is a view illustrating a transfer track in a sliding direction of a hand unit of a transferring apparatus according to a comparative example.

### DETAILED DESCRIPTION OF THE DISCLOSURE

Hereinafter, the preferred embodiment of the present disclosure will be described in detail with reference to the accompanying drawings. Advantages and features of the present disclosure and methods of achieving the advantages and features will be apparent from the following embodiments that will be described in more detail with reference to the accompanying drawings. It should be noted, however, that the present disclosure is not limited to the following embodiments and may be implemented in various forms. The embodiments are provided only to disclose the present disclosure and let those skilled in the art understand the scope of the present disclosure. In the drawings, the embodiments of the present disclosure are defined by the scope of claims. The same reference numerals denote the same elements throughout the specification.

The terms used herein are for the purpose of embodiments and are not intended to be limit the present disclosure. In the present disclosure, unless referred to the contrary, the singular forms are intended to include the plural forms. The terms “comprises” and/or “comprising” used herein specify the presence of stated elements, steps, operations and/or targets but do not preclude the presence or addition of one or more other elements, steps, operations and/or targets.

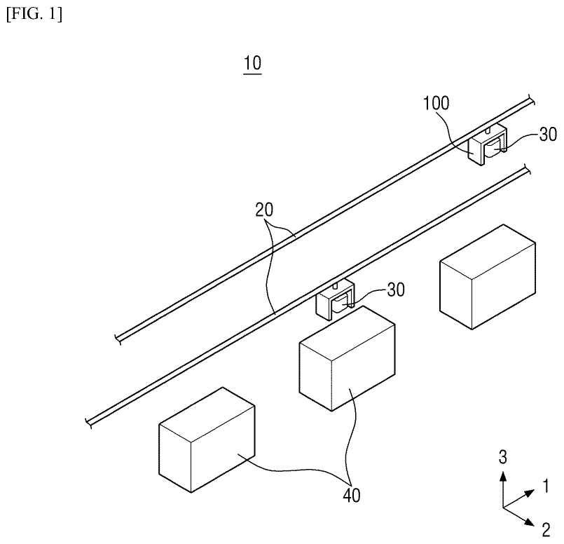

FIG. 1 is a view illustrating a fabricating factory in which a transferring apparatus according to some embodiments of the present disclosure is provided.

Referring to FIG. 1, a fabricating factory 10 of the present embodiment may be a factory that fabricates semiconductors (or displays). The fabricating factory 10 may be provided with a plurality of fabrication facilities (fabs, not shown). The plurality of fabs may be provided as a clean room, and a plurality of substrate processing apparatuses (not shown) for performing a semiconductor fabricating process may be installed.

For example, the plurality of substrate processing apparatuses may process a number of fabricating processes, such as a deposition process, a lithography process and an etching process, on a substrate (e.g., a wafer).

After the substrate fabricating process is performed in any one substrate processing apparatus, the substrate may be transferred to another substrate processing apparatus for next fabricating process. The substrate processing apparatus may process the substrate by taking out the substrate from a transfer target 30 mounted on a mounting position such as a load port. In addition, the substrate processing apparatus may accommodate the processed substrate in the transfer target 30 mounted on the mounting position.

That is, the substrate may be transferred while being stored in the transfer target 30 capable of accommodating a plurality of substrates. For example, the transfer target 30 may be a front opening unified pod (FOUP) in which the plurality of substrates are accommodated. However, the transfer target 30 is not limited to the FOUP, and may be a magazine in which a chip is accommodated. In this way, various examples may be made in the target transfer 30.

The transfer target 30 in which the substrate or the chip is stored may be transferred by the transferring apparatus 100. In order for the transfer target 30 to be transferred between the plurality of substrate processing apparatuses in the fabricating factory 10 or the transfer target 30 to be transferred to a plurality of fabs, a rail unit 20 may form a moving path in the fabricating factory 10.

The transferring apparatus 100 may move along the moving path formed by the rail unit 20. That is, a transfer path for transferring the transfer target 30 may be formed between the plurality of substrate processing apparatuses. The transfer path is a moving path of the transferring apparatus 100, and may form an installation path of the rail unit 20. For example, the rail unit 20 may be provided on the ceiling.

The rail unit 20 provided to the fab may have a structure in which a straight line and a curved line are combined with each other. The rail unit 20 is provided with a plurality of bays in which a transfer operation is performed for usability of a work space and easiness of management of the transferring apparatus 100, and the plurality of bays are connected to one, so that the transferring apparatus 100 may move to a plurality of bays adjacent to each other without moving only in any one of the plurality of bays.

The rail unit 20 may be provided with a power supply cable (not shown) for supplying power in a high-efficiency inductive (HID) power distribution or a contactless power supply (CPS) to the transferring apparatus 100. The power supply cable may be installed on all or some of the rail unit 20.

The transferring apparatus 100 for moving the rail unit 20 provided on the ceiling may be provided as an overhead hoist transport (OHT). For example, when the transferring apparatus 100 transfers the transfer target 30 between the plurality of substrate processing apparatuses, the transfer target 30 may be directly transferred from one substrate processing apparatus to another substrate processing apparatus, or the transfer target 30 may be stored in the stocker 40 and then transferred to another substrate processing apparatus.

Hereinafter, the transferring apparatus 100 will be described with reference to the drawings.

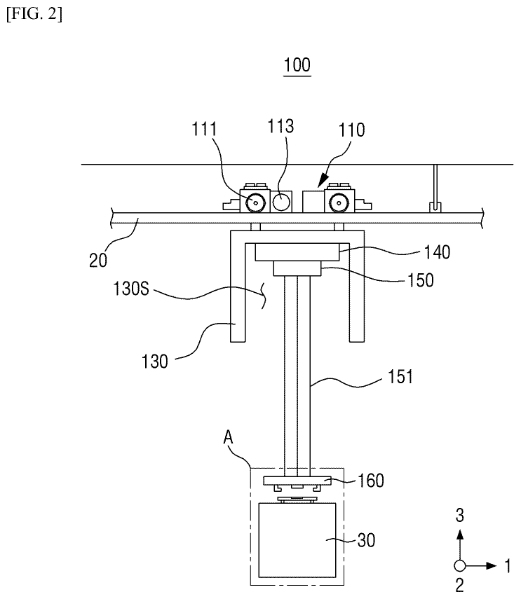

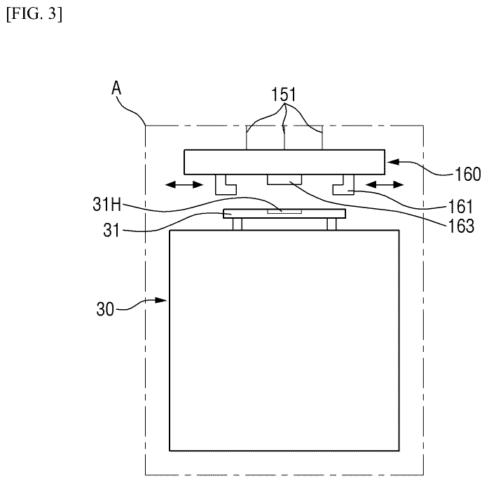

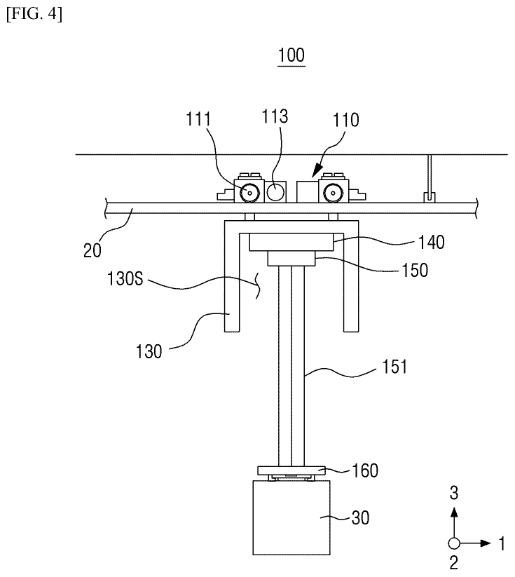

FIG. 2 is a view illustrating a state that a transferring apparatus according to some embodiments of the present disclosure descends toward a transfer target, FIG. 3 is a view illustrating an area A of FIG. 2, and FIG. 4 is a view illustrating a state that a transferring apparatus according to some embodiments of the present disclosure grips a transfer target.

Referring to FIGS. 2 to 4, the transferring apparatus 100 may include a driving unit 110, a housing 130, a horizontal moving unit 140, a hoist unit 150 and a hand unit 160.

The driving unit 110 may be provided with a driving wheel 111 rotated by a motor 113 so that the driving unit 110 drives along the driving rail 20. The driving unit 110 may drive while rotating in a state that the driving wheel 111 is in contact with the driving rail 20.

A steering wheel (not shown) may be provided on an upper surface of the driving unit 110. The steering wheel may be provided to be movable along a direction 2 perpendicular to the driving direction 1 of the driving unit 110 in a horizontal direction, that is, a direction 2 in which the horizontal moving unit 140 slides. The steering wheel may be selectively in contact with a straight steering rail (not shown) for guiding straight driving and a branch steering rail (not shown) for guiding branch driving.

The housing 130 may be connected to the driving unit 110 below the driving rail 20. The housing 130 may be formed with an inner space 130S. The housing 130 may have a structure in which a lower side and both side (front and rear based on FIG. 2) or one side (front based on FIG. 2) are opened for vertical movement and horizontal movement of the transfer target 30. In this case, both sides of the housing 130 may be the direction 2 in which the horizontal moving unit 140 slides.

The horizontal moving unit 140, the hoist unit 150 and the hand unit 160 may transfer the transfer target 30 through the open bottom of the housing 130 when the transfer target 30 is to be transferred from a mounting place to the inner space 130S or when the transfer target 30 is to be transferred from the inner space 130S to the mounting place. That is, the horizontal moving unit 140, the hoist unit 150 and the hand unit 160 may be installed in the housing 130 to load and unload the transfer target 30.

The horizontal moving unit 140 may be provided on an upper surface inside the housing 130. The horizontal moving unit 140 may perform horizontal movement such as a sliding operation through the open side of the housing 130. For example, the horizontal moving unit 140 may include a guide rail (not shown) and a moving block (not shown) to slide in a horizontal direction, or may include a plurality of sliding plates (not shown), a ball bearing and the like.

This horizontal moving unit 140 may move the hoist unit 150 relative to the housing 130 by moving in an orthogonal direction with respect to the driving direction 1 of the driving unit 110, that is, in the sliding direction 2.

The hoist unit 150 may be provided below the horizontal moving unit 140, and may be horizontally moved by the horizontal moving unit 140. The hoist unit 150 may ascend and descend the hand unit 160. To this end, the hoist unit 150 may include a belt unit 151 and a hoist driving unit 155.

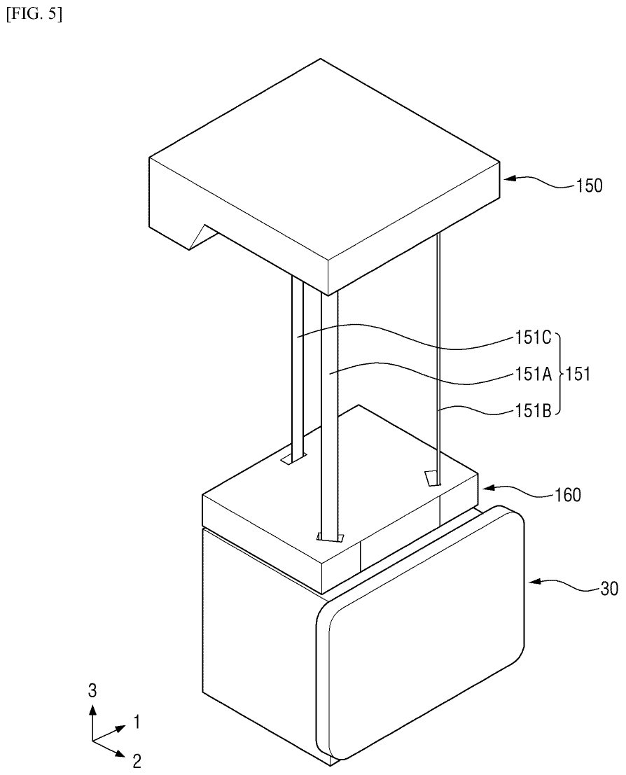

The belt unit 151 may vertically move the hand unit 160 by a driving force of the hoist driving unit 155. The hoist driving unit 155 may wind or unwind the belt unit 151 by generating the driving force, that is, vertically move the hand unit 160 by adjusting a length of the belt unit 151, thereby adjusting a height. Such a hoist unit 150 will be described with reference to FIGS. 5 to 11.

The hand unit 160 may be moved in the vertical direction in the housing 130 by the hoist unit 150, and may pick up the transfer target 30. For example, the hand unit 160 may be fixed to a lower end of the belt unit 151 and connected to the hoist unit 150 through the belt unit 151. The hand unit 160 may be provided in parallel with a bottom surface. That is, heights of lower ends of three hoist belts (a first hoist belt 151A, a second hoist belt 151B and a third hoist belt 151C) may be provided equally so that the hand unit 160 may be provided to be parallel with the bottom surface.

The hand unit 160 may include a gripper 161 for gripping the transfer target and a gripper motor (not shown) for driving the gripper 161. The gripper 161 may be provided to be slid by the gripper motor to interfere with the transfer target 30 or to release the interference.

Referring to FIGS. 3 and 4, for example, a grip operation may be performed in such a manner that, when a cone 163 provided in the hand unit 160 is inserted into a groove 31H of the transfer target 30 and the cone 163 is in contact with the groove 31H, it is determined that a sensor (not shown) provided in the cone 163 has detected the transfer target 30, so that the gripper 161 slides to be close to a plate 31 of the transfer target 30.

However, since the sensor of the cone 163 is a contact sensor and may detect contacting only an object as being in contact with the groove 31H of the transfer target 30, even though the belt unit 151 of the hoist unit 150 is shaken a lot and is not fitted into a correct position of the groove 31H, an error recognized as being normally fitted into the groove 31H may occur. Therefore, the gripper 161 may be fitted into the plate 31 at a position where the gripper 161 is not exactly fitted into the plate 31 of the transfer target 30.

Then, a problem such as the fall of the transfer target 30 may occur in the transfer process of the transfer target 30 or a gripping state of the gripper 161 may not be normally performed and thus the gripper 161 may be damaged. In order to solve the problem, it is necessary to minimize shaking of the belt unit 151. That is, when the shaking of the belt unit 151 is minimized, since the hand unit 160 may be disposed at a correct position and thus the cone 163 may be accurately fitted into the groove 31H, an error in the gripping operation of the gripper 161 may be minimized or avoided. To this end, the hoist unit 150 of the present embodiment improves the belt unit 151.

Hereinafter, the hoist unit 150 will be described in detail with reference to the drawings.

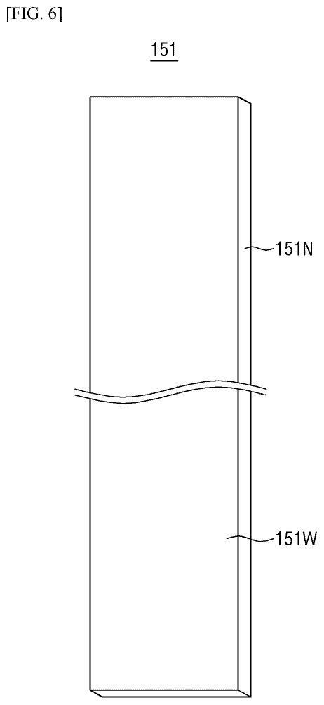

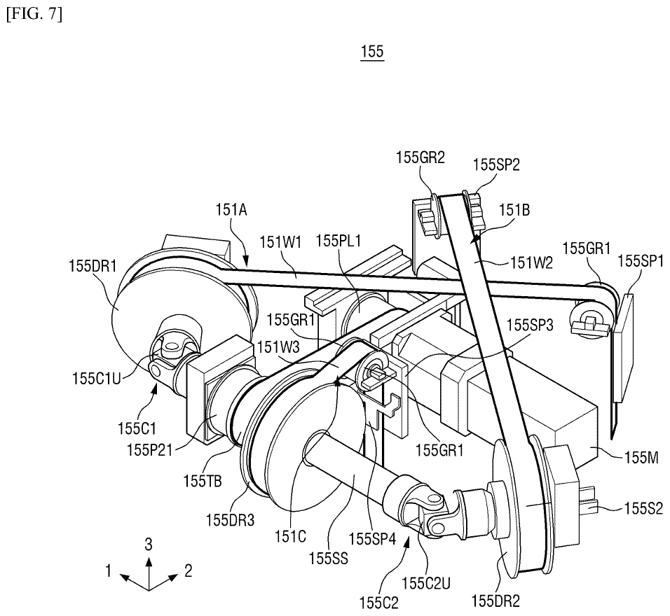

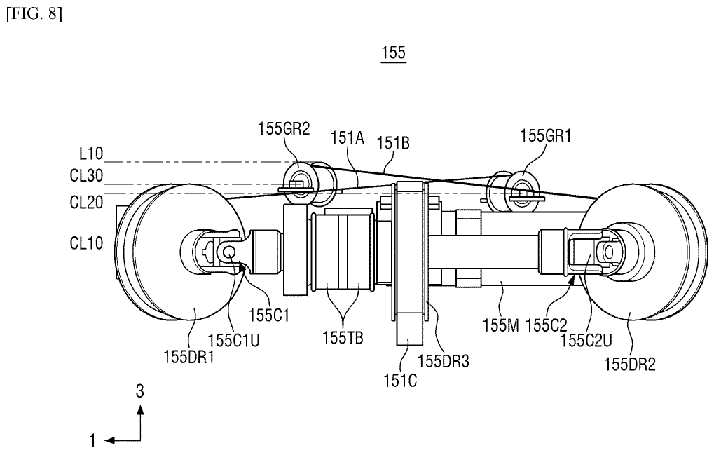

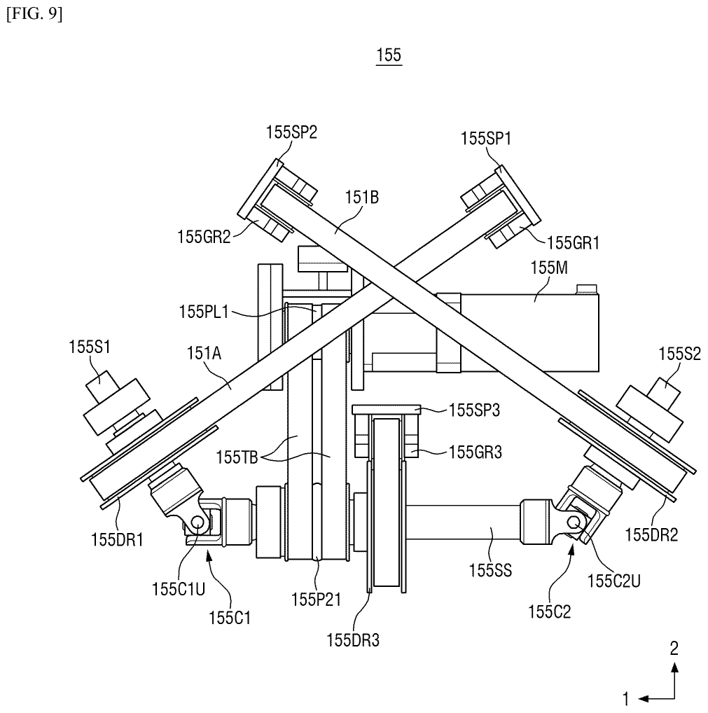

FIG. 5 is a view illustrating a state that a belt unit of a transferring apparatus according to some embodiments of the present disclosure is unwound, FIG. 6 is a view illustrating a belt unit of a transferring apparatus according to some embodiments of the present disclosure, FIG. 7 is a perspective view illustrating a hoist unit of a transferring apparatus according to the first embodiment of the present disclosure, FIG. 8 is a rear view illustrating a hoist unit of a transferring apparatus according to the first embodiment of the present disclosure, and FIG. 9 is a plan view illustrating a hoist unit of a transferring apparatus according to the first embodiment of the present disclosure.

Referring to FIGS. 5 to 9, the hoist unit 150 of the first embodiment may include a belt unit 151 and a hoist driving unit 155.

The belt unit 151 may be connected to the hand unit 160, and an end of the belt unit 151 may be fixed to the hand unit 160 without friction and detachment, or may be fixed thereto in various ways, such as being fixed thereto by a bolt or an adhesive.

The belt unit 151 may include a first hoist belt 151A, a second hoist belt 151B and a third hoist belt 151C so that they may be connected to three points of the hand unit 160.

The belt unit 151 of the present embodiment may be disposed not to have a large deformation rate. For example, the first hoist belt 151A and the second hoist belt 151B may be provided such that a wide surface 151W having a large deformation rate does not face the sliding direction 2 of the horizontal moving unit 140, that is, may be provided not to be in parallel, so that the shaking of the hand unit 160 by the belt unit 151 may be minimized. In addition, the three hoist belts (the first hoist belt 151A, the second hoist belt 151B and the third hoist belt 151C) may be disposed not to be parallel with one another, that is, the wide surfaces 151W having a large deformation rate do not face each other in the same direction and are disposed to misaligned without being parallel with each other, thereby reducing the deformation rate of adjacent hoist belts. This is because that the three hoist belts (the first hoist belt 151A, the second hoist belt 151B and the third hoist belt 151C) have different deformation directions and thus prevent deformation of adjacent hoist belts.

In this case, referring to FIG. 6, the wide surface 151W refers to a surface where a width of the belt unit 151 is wide. That is, each of the first hoist belt 151A, the second hoist belt 151B and the third hoist belt 151C has a width that is not a shape of a string. In addition, the wide surface 151W not a narrow surface 151N in the belt unit 151 is defined as a first surface 151W1, a second surface 151W2 and a third surface 151W3. That is, the first surface 151W1 refers to the wide surface 151W of the first hoist belt 151A, the second surface refers to the wide surface 151W of the second hoist belt 151B, and the third surface 151W3 refers to the wide surface 151W of the third hoist belt 151C. The wide surface 151W includes both front and rear surfaces based on FIG. 6, for example, the first surface 151W1 refers to both the front and rear surfaces which are the wide surfaces 151W of the first hoist belt 151A.

As shown in FIG. 5, the first hoist belt 151A, the second hoist belt 151B and the third hoist belt 151C of the present embodiment may be disposed toward a central direction of the housing 130 between the hoist unit 150 and the hand unit 160. For example, the first surface 151W1 and the second surface 151W2 may be disposed to be misaligned at an angle without being parallel with respect to each of the driving direction 1 of the driving unit 110 and the sliding direction 2 that is the moving direction of the horizontal moving unit 140. For example, a width of the third surface 151W3 may be parallel with the driving direction 1 to form 0°/180°, a width of the first surface 151W1 may form an acute angle (e.g., 60°) with respect to the driving direction 1, and a width of the second surface 151W2 may form a symmetrical obtuse angle (e.g., 120°) with respect to the first surface 151W1.

In addition, referring to FIG. 7, the first surface 151W1 between a first drum 155DR1 and a first guide roller 155GR1 and the second surface 151W2 between a second drum 155DR2 and a second guide roller 155GR2 may cross with each other to form an ‘X’ shape. The third surface 151W3 of the third hoist belt 151C may face a point where the first surface 151W1 and the second surface 151W2 cross each other.

The hoist driving unit 155 may be configured to wind or unwind the belt unit 151.

The hoist driving unit 155 may include a motor 155M, a driving pulley 155PL1, a driven pulley 155P21, an input shaft 155SS, a first connector 155C1, a second connector 155C2, a first output shaft 155S1, a second output shaft 155S2, a first drum 155DR1, a second drum 155DR2, a third drum 155DR3, a first guide roller 155GR1, a second guide roller 155GR2, a third guide roller 155GR3, a first anti-shaking plate 155SP1, a second anti-shaking plate 155SP2 and a third anti-shaking plate 155SP3.

The motor 155M may include a motor shaft (not shown). The motor 155M of the present embodiment may be provided as one to drive the belt unit 151 that includes three hoist belts (the first hoist belt 151A, the second hoist belt 151B and the third hoist belt 151C). The driving pulley 155PL1 and the driven pulley 155P21 may be connected to the motor 155M so that three hoist belts are wound or unwound by the operation of one motor 155M.

The driving pulley 155PL1 is directly connected to the motor shaft so that a rotational force of the motor 155M may be directly transferred thereto. The driven pulley 155P21 may be positioned on the same central axis as that of the third drum 155DR3 in adjacent to the driving pulley 155PL1, and may be connected to the driving pulley 155PL1 by a timing belt 155TB so that the rotational force from the driving pulley 155PL1 to which the rotational force of the motor 155M is transferred may be transferred thereto.

The input shaft 155SS may be extended to both sides of the driven pulley 155P21 so that the rotational force is transferred from both sides of the driven pulley 155P21 to the first drum 155DR1 and the third drum 155DR3 while receiving the rotational force of the driven pulley 155P21.

Each of the first connector 155C1 and the second connector 155C2 may be connected to the input shaft 155SS so that angles of the first output shaft 155S1 and the second output shaft 155S2 with respect to the input shaft 155SS form acute or obtuse angles.

For example, the first connector 155C1 may be connected to one end (left side based on FIGS. 7 and 9) of the input shaft 155SS at an acute angle (e.g., 60°), and the second connector 155C2 may be connected to the other end (right side based on FIG. 7) of the input shaft 155SS at an obtuse angle (e.g., 120°) symmetrical to the first connector 155C1. The first connector 155C1 and the second connector 155C2 may be provided as universal joints 155C1U and 155C2U, respectively.

The first output shaft 155S1 may be connected to the first connector 155C1 to rotate the first drum 155DR1 by receiving the rotational force of the input shaft 155SS while being bent from the input shaft 155SS.

The second output shaft 155S2 may be connected to the second connector 155C2 to rotate the second drum 155DR2 by receiving the rotational force of the input shaft 155SS while being bent from the input shaft 155SS.

The first drum 155DR1 may be connected to the first output shaft 155S1 to rotate in conjunction with the first output shaft 155S1, and the first hoist belt 151A may be wound thereon. A central axis of the first drum 155DR1 is the same as a central axis of the first output shaft 155S1 of which angle is bent by the first connector 155C1, so that the first surface 151W1 between the first drum 155DR1 and the first guide roller 155GR1 may be disposed to be transverse in a diagonal direction from the upper surface of the hand unit 160.

The second drum 155DR2 may be connected to the second output shaft 155S2 to rotate in conjunction with the second output shaft 155S2, and the second hoist belt 151B may be wound thereon. A central axis of the second drum 155DR2 is the same as a central axis of the second output shaft 155S2 of which angle is bent by the second connector 155C2, so that the second surface 151W2 between the second drum 155DR2 and the second guide roller 155GR2 may be disposed to be transverse in a diagonal direction from the upper surface of the hand unit 160.

Therefore, as shown in FIGS. 7 and 9, when viewed from the top, the first surface 151W1 and the second surface 151W2 may cross each other, and thus may be disposed in an X shape.

The third drum 155DR3 may surround the input shaft 155SS to receive the rotational force of the input shaft 155SS, the third hoist belt 151C may be wound thereon, and may be disposed to be spaced apart from the first drum 155DR1 and the second drum 155DR2 between the first drum 155DR1 and the second drum 155DR2.

The first guide roller 155GR1 may guide movement of the first hoist belt 151A. A surface of the first guide roller 155GR1, on which the first hoist belt 151A is wound, may face a surface of the first drum 155DR1, on which the first hoist belt 151A is wound. A gap between the first guide roller 155GR1 and the first drum 155DR1 may be greater than a gap between the third guide roller 155GR3 and the third drum 155DR3.

The second guide roller 155GR2 may guide movement of the second hoist belt 151B. A surface of the second guide roller 155GR2, on which the second hoist belt 151B is wound, may face a surface of the second drum 155DR2, on which the second hoist belt 151B is wound. A gap between the second guide roller 155GR2 and the second drum 155DR2 may be the same as a gap between the first guide roller 155GR1 and the first drum 155DR1.

At a point where the second surface 151W2 and the first surface 151W1 cross each other, a height of the second guide roller 155GR2 may be different from that of the first guide roller 155GR1 so as not to rub against each other.

For example, referring to FIG. 8, the first drum 155DR1 and the second drum 155DR2 may have the same central axis CL10, and a central axis CL20 of the first guide roller 155GR1 may be lower than a central axis CL30 of the second guide roller 155GR2, whereby a height L10 of the second guide roller 155GR2 may be higher than the height of the first guide roller 155GR1.

However, ends of the first hoist belt 151A, the second hoist belt 151B and the third hoist belt 151C may have the same height so that the hand unit 160 is horizontal with respect to the bottom surface.

The third guide roller 155GR3 may guide movement of the third hoist belt 151C. A surface of the third guide roller 155GR3, on which the third hoist belt 151C is wound, may face a surface of the third drum 155DR3, on which the third hoist belt 151C is wound. Each of the first guide roller 155GR1, the second guide roller 155GR2 and the third guide roller 155GR3 may be disposed at the rear or the front based on FIG. 7 with respect to each of the first drum 155DR1, the second drum 155DR2 and the third drum 155DR3.

Each of the first anti-shaking plate 155SP1, the second anti-shaking plate 155SP2 and the third anti-shaking plate 155SP3 is disposed not to be in contact with the belt unit 151 to prevent the belt unit 151 from shaking or minimize shaking of the belt 151 while preventing interference or friction with movement of the belt unit 151 from occurring.

The first hoist belt 151A may be disposed on the first anti-shaking plate 155SP1 between the first guide rollers 155GR1. The second hoist belt 151B may be disposed on the second anti-shaking plate 155SP2 between the second guide rollers 155GR2. The third hoist belt 151C may be disposed on the third anti-shaking plate 155SP3 between the third guide rollers 155GR3.

In addition, the third anti-shaking plate 155SP3 may be provided with an auxiliary plate 155SP4 to face the auxiliary plate 155SP4 to prevent the belt unit 151 from shaking or minimize shaking of the belt unit 151 by blocking the belt unit 151 in different directions. In addition, the first anti-shaking plate 155SP1 and the second anti-shaking plate 155SP2 may be also provided with an auxiliary plate (not shown) identically/similarly to the third anti-shaking plate 155SP3.

Such a hoist driving unit 155 may be covered by a box-shaped main body (not shown) and/or a cover, and may be installed on the main body by ribs and bolts.

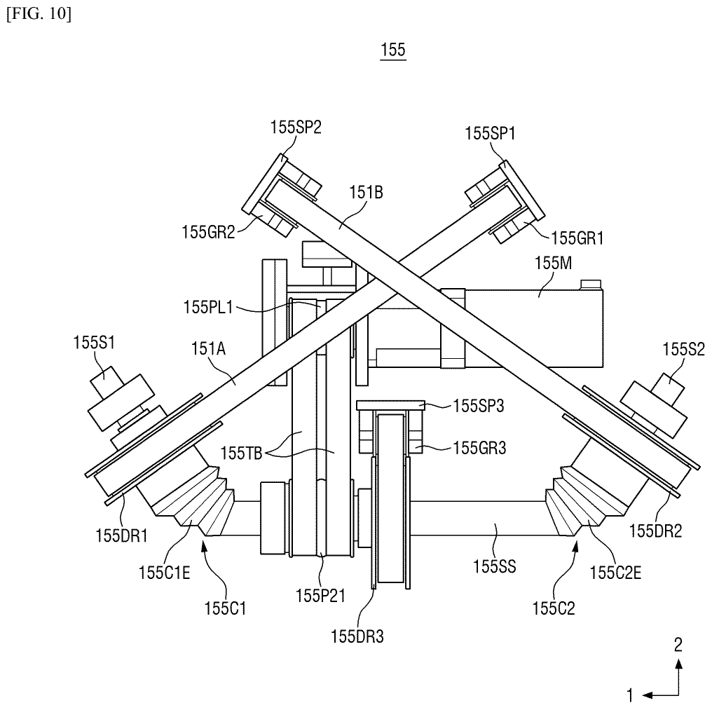

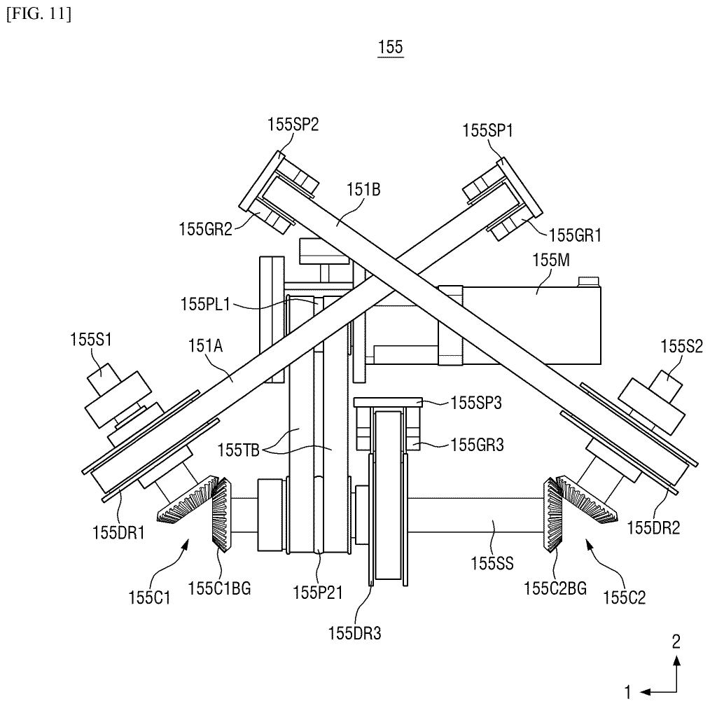

Hereinafter, a modified example of the present embodiment will be described with reference to FIGS. 10 and 11, and a redundant description of the same elements performing the same function will be omitted.

FIG. 10 is a plan view illustrating a hoist unit of a transferring apparatus according to the second embodiment of the present disclosure. Referring to FIG. 10, the following description will be based on differences from the description made with reference to FIGS. 7 to 9.

Referring to FIG. 10, the transferring apparatus 100 of the second embodiment differs from that of the first embodiment in that the first connector 155C1 and the second connector 155C2 are provided as constant velocity joints 155C1E and 155C2E, respectively.

The constant velocity joints 155C1E and 155C2E may include a ball (not shown) and a cage (not shown) to transfer a rotational force of the input shaft 155SS to the first output shaft 155S1 and the second output shaft 155S2, respectively.

A bellows (not shown as a reference numeral) may be provided outside the constant velocity joints 155C1E and 155C2E so that an internal structure (ball, cage, etc.) is partitioned from the outside, but the present disclosure is not limited thereto.

FIG. 11 is a plan view illustrating a hoist unit of a transferring apparatus according to the third embodiment of the present disclosure. Referring to FIG. 11, the following description will be based on differences from the description made with reference to FIGS. 7 to 10.

Referring to FIG. 11, the transferring apparatus 100 of the third embodiment is different from that of the first embodiment and the second embodiment in that the first connector 155C1 and the second connector 155C2 are provided as bevel gears 155C1BG and 155C2BG, respectively. That is, the third embodiment is different from the first embodiment and the second embodiment in that the first connector 155C1 is provided as the first bevel gear 155C1BG and the second connector 155C2 is provided as the second bevel gear 155C2BG. The bevel gears 155C1BG and 155C2BG may respectively transfer the rotational force of the input shaft 155SS to the first output shaft 155S1 and the second output shaft 155S2 equally/similarly to the constant velocity joints 155C1E and 155C2E.

In addition, although not shown in the drawing, various modifications may be made in the bevel gears 155C1BG and 155C2BG, like that a bellows is provided on the outside so that an internal structure (engagement of the bevel gears 155C1BG and 155C2BG) is partitioned from the outside equally/similarly to the constant velocity joints 155C1E and 155C2E.

Hereinafter, the hoist belt of the comparative example will be described with reference to the drawings.

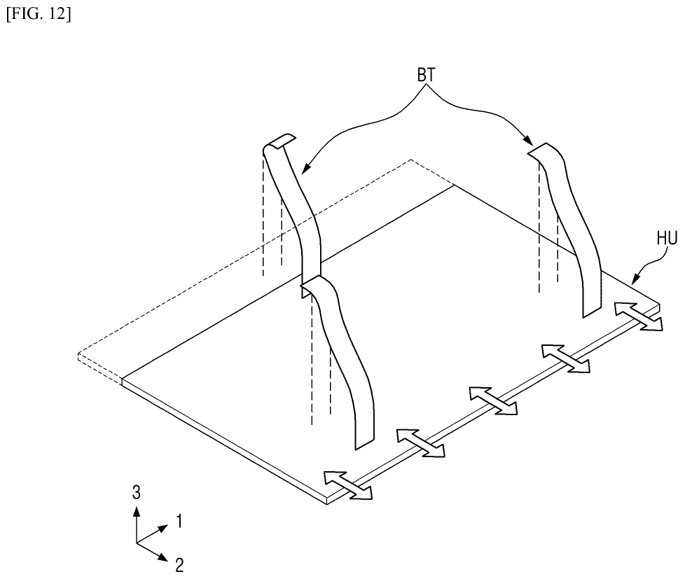

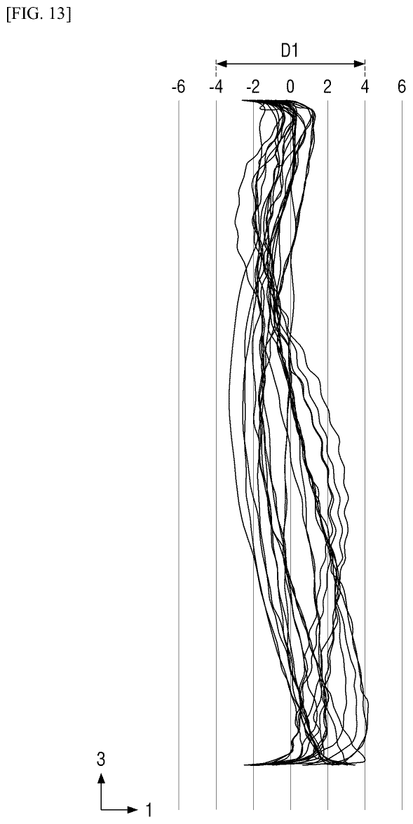

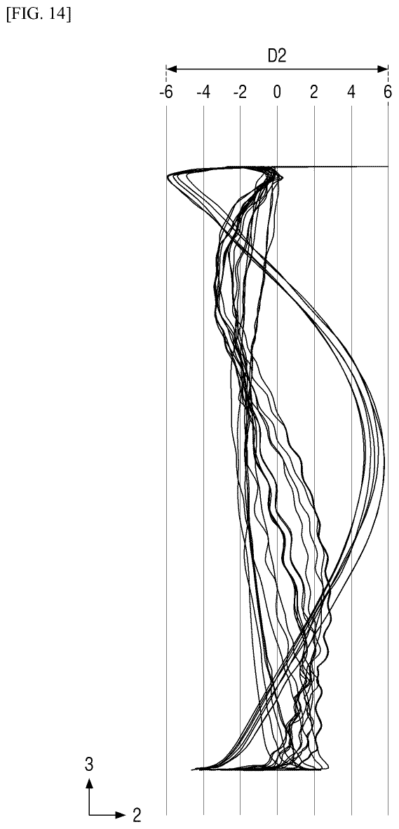

FIG. 12 is a view illustrating arrangement of a hoist belt according to a comparative example, FIG. 13 is a view illustrating a transfer track in a driving direction of a hand unit of a transferring apparatus according to a comparative example, and FIG. 14 is a view illustrating a transfer track in a sliding direction of a hand unit of a transferring apparatus according to a comparative example.

First, referring to FIG. 12, since a wide surface of the hoist belt BT has a larger deformation rate than a narrow surface, when the hoist belt BT is disposed in parallel with the sliding direction 2 of the hand unit 160, the hoist belt BT may be greatly deformed with respect to the sliding direction 2 of the hand unit 160. That is, the three hoist belts BT may be deformed together without blocking the deformation from one another.

When the hoist belt BT is released so that the hand unit 160 grips the transfer target 30, the hand unit 160 descends and shakes not only in the driving direction 1 but also in the sliding direction 2, whereby the hand unit 160 may be greatly shaken by the large deformation rate of the wide surface of the hoist belt BT.

That is, when the hand unit 160 descends as shown in FIG. 13, the hoist belt BT is deformed, so that the track of the hand unit 160 during descending may not be perpendicular to the driving direction 1 of the transferring apparatus 100 and a first deformation rate D1 may occur.

In addition, as shown in FIG. 14, when the hand unit 160 descends, the hoist belt BT is deformed, so that the track of the hand unit 160 during descending may not be perpendicular to the sliding direction 2 of the hand unit 160 and a second deformation rate D2 may occur.

Meanwhile, in the transferring apparatus 100 according to the embodiments of the present disclosure, the first hoist belt 151A and the second hoist belt 151B are disposed to be misaligned at an angle without being parallel with respect to the driving direction 1 of the driving unit 110 and the sliding direction 2 that is the moving direction of the horizontal moving unit 140, that is, the three hoist belts (the first hoist belt 151A, the second hoist belt 151B and the third hoist belt 151C) have different deformation directions and thus deformation of the adjacent hoist belts may be blocked, whereby the deformation rate may be less than that of the hoist belt BT of the comparative example.

Although the embodiments of the present disclosure have been described with reference to the accompanying drawings, it will be apparent to those skilled in the art that the present disclosure may be embodied in other specific forms without departing from the technical spirits and essential characteristics of the present disclosure. Thus, the above-described embodiments are to be considered in all respects as illustrative and not restrictive.

What is claimed is:

1. A transferring apparatus comprising:
a driving unit provided with a driving wheel and connected with a housing;
a hoist unit provided in the housing; and
a hand unit provided with a gripper that grips a transfer target,
wherein the hoist unit includes:
a belt unit connected to the hand unit, including a first hoist belt and a second hoist belt; and
a hoist driving unit configured to wind or unwind the belt unit, and
each of a first surface of the first hoist belt and a second surface of the second hoist belt is disposed to be misaligned at an angle with a driving direction of the driving unit without being parallel with the driving direction of the driving unit.

2. The transferring apparatus of claim 1, further comprising a horizontal moving unit moving in a direction orthogonal to the driving direction of the driving unit between the housing and the hoist unit to move the hoist unit relative to the housing,
wherein each of the first surface and the second surface is disposed to be misaligned at an angle without being parallel with the moving direction of the horizontal moving unit.

3. The transferring apparatus of claim 1, wherein each of the first surface of the first hoist belt and the second surface of the second hoist belt is disposed toward a central direction of the housing rather than the driving direction of the driving unit.

4. The transferring apparatus of claim 1, wherein the belt unit further includes a third hoist belt connected to the hand unit and disposed to be spaced apart from each of the first hoist belt and the second hoist belt.

5. The transferring apparatus of claim 4, wherein the hoist driving unit includes:
a motor provided with a motor shaft;
a driving pulley connected to the motor shaft to receive a rotational force of the motor;
a driven pulley connected to the driving pulley by a timing belt;
an input shaft extended to both sides of the driven pulley;
a first connector connected to one end of the input shaft at an acute or obtuse angle;
a second connector connected to the other end of the input shaft at an acute or obtuse angle;
a first output shaft connected to the first connector;
a second output shaft connected to the second connector;
a first drum connected to the first output shaft, on which the first hoist belt is wound;
a second drum connected to the second output shaft, on which the second hoist belt is wound; and
a third drum surrounding the input shaft to receive a rotational force of the input shaft, on which the third hoist belt is wound.

6. The transferring apparatus of claim 5, wherein each of the first connector and the second connector includes a bevel gear.

7. The transferring apparatus of claim 5, wherein each of the first connector and the second connector includes a constant velocity joint.

8. The transferring apparatus of claim 5, wherein each of the first connector and the second connector includes a universal joint.

9. The transferring apparatus of claim 5, wherein the hoist driving unit further includes:
a first guide roller guiding movement of the first hoist belt while facing the first drum;
a second guide roller guiding movement of the second hoist belt while facing the second drum; and
a third guide roller guiding movement of the third hoist belt while facing the third drum.

10. The transferring apparatus of claim 9, wherein the hoist driving unit further includes:
a first anti-shaking plate on which the first hoist belt is disposed between the first guide rollers;
a second anti-shaking plate on which the second hoist belt is disposed between the second guide rollers; and
a third anti-shaking plate on which the third hoist belt is disposed between the third guide rollers.

11. The transferring apparatus of claim 9, wherein the first surface between the first drum and the first guide roller crosses the second surface between the second drum and the second guide roller.

12. The transferring apparatus of claim 11, wherein the first guide roller has a different height from the second guide roller.

13. The transferring apparatus of claim 11, wherein a third surface of the third hoist belt faces a point where the first surface of the first hoist belt and the second surface of the second hoist belt cross each other.

14. A transferring apparatus comprising:
a driving unit provided with a driving wheel and connected with a housing;
a hoist unit provided in the housing;
a horizontal moving unit moving in a direction orthogonal to a driving direction of the driving unit between the housing and the hoist unit to move the hoist unit relative to the housing; and
a hand unit provided with a gripper that grips a transfer target,
wherein the hoist unit includes:
a belt unit connected to the hand unit, including a first hoist belt and a second hoist belt; and
a hoist driving unit configured to wind or unwind the belt unit, and
a first surface of the first hoist belt and a second surface of the second hoist belt are disposed in an X shape by crossing each other at an upper portion, and are extended in a downward direction.

15. The transferring apparatus of claim 14, wherein the belt unit further includes a third hoist belt connected to the hand unit and disposed to be spaced apart from each of the first hoist belt and the second hoist belt.

16. The transferring apparatus of claim 15, wherein the hoist driving unit includes:
a motor provided with a motor shaft;
a driving pulley connected to the motor shaft to receive a rotational force of the motor;
a driven pulley connected to the driving pulley by a timing belt;
an input shaft extended to both sides of the driven pulley;
a first connector connected to one end of the input shaft at an acute or obtuse angle;
a second connector connected to the other end of the input shaft at an acute or obtuse angle symmetrical with the first connector;
a first output shaft connected to the first connector;
a second output shaft connected to the second connector;
a first drum connected to the first output shaft, on which the first hoist belt is wound;
a second drum connected to the second output shaft, on which the second hoist belt is wound; and
a third drum surrounding the input shaft to receive a rotational force of the input shaft, on which the third hoist belt is wound.

17. The transferring apparatus of claim 16, wherein each of the first connector and the second connector includes a bevel gear.

18. The transferring apparatus of claim 16, wherein the hoist driving unit further includes a first guide roller guiding movement of the first hoist belt while facing the first drum, a second guide roller guiding movement of the second hoist belt while facing the second drum, and a third guide roller guiding movement of the third hoist belt while facing the third drum, and
the first surface between the first drum and the first guide roller crosses the second surface between the second drum and the second guide roller.

19. A transferring apparatus provided in a semiconductor fabricating factory, the transferring apparatus comprising:
a driving unit provided with a driving wheel and connected with a housing;
a hoist unit provided in the housing;
a horizontal moving unit moving in a direction orthogonal to a driving direction of the driving unit between the housing and the hoist unit to move the hoist unit relative to the housing; and
a hand unit provided with a gripper that grips a transfer target,
wherein the hoist unit includes:
a belt unit connected to the hand unit, including a first hoist belt, a second hoist belt and a third hoist belt; and
a hoist driving unit configured to wind or unwind the belt unit,
the hoist driving unit includes:
a motor provided with a motor shaft;
a driving pulley connected to the motor shaft to receive a rotational force of the motor;
a driven pulley connected to the driving pulley by a timing belt;
an input shaft extended to both sides of the driven pulley;
a first bevel gear connected to one end of the input shaft at an acute angle;
a second bevel gear connected to the other end of the input shaft at an obtuse angle symmetrical with the first bevel gear;
a first output shaft connected to the first bevel gear;
a second output shaft connected to the second bevel gear;
a first drum connected to the first output shaft, on which the first hoist belt is wound;
a second drum connected to the second output shaft, on which the second hoist belt is wound;
a third drum surrounding the input shaft to receive a rotational force of the input shaft, on which the third hoist belt is wound, and disposed between the first drum and the second drum;
a first guide roller guiding movement of the first hoist belt while facing the first drum;
a second guide roller guiding movement of the second hoist belt while facing the second drum;
a third guide roller guiding movement of the third hoist belt while facing the third drum;
a first anti-shaking plate on which the first hoist belt is disposed between the first guide rollers;
a second anti-shaking plate on which the second hoist belt is disposed between the second guide rollers; and
a third anti-shaking plate on which the third hoist belt is disposed between the third guide rollers,
each of a first surface of the first hoist belt and a second surface of the second hoist belt is disposed toward a central direction of the housing rather than the driving direction of the driving unit, and thus is disposed to be misaligned at an angle without being parallel with each of the driving direction of the driving unit and the moving direction of the horizontal moving unit,
the first surface between the first drum and the first guide roller and the second surface between the second drum and the second guide roller cross each other to constitute an ‘X’ shape, and
a third surface of the third hoist belt faces a point where the first surface of the first hoist belt and the second surface of the second hoist belt cross each other.
